(19) United States
(12) Patent Application Publication
(10) Pub. No.: US 2013/0167769 A1
(43) Pub. Date: Jul. 4, 2013

(54) TARGETED TEMPERATURE COMPENSATION IN CHEMICAL VAPOR DEPOSITION SYSTEMS

(71) Applicant: Bassam Shamoun, Plainview, NY (US)

(72) Inventor: Bassam Shamoun, Plainview, NY (US)

(21) Appl. No.: 13/340,226

(22) Filed: Dec. 29, 2011

(51) Int. Cl. C30B 25/10; C30B 25/16

(52) U.S. Cl. 117/86; 118/712

(57) ABSTRACT

Targeted temperature compensation for use with a chemical vapor deposition (CVD) apparatus. A localized temperature monitoring system is configured to provide localized temperature information representing surface temperatures of portions of the one or more wafers on a wafer carrier while the wafer carrier is rotating in a CVD process. A temperature profiling system is configured to generate a temperature profile that is indicative of localized cold spots on a surface of the one or more wafers. The temperature profile is based on the localized temperature information. A targeted heating system is configured to selectively apply localized heat to the localized cold spots dynamically based on the temperature profile such that a thermal distribution of the surface of the one or more wafers is made more uniform while a CVD process is carried out on the CVD apparatus.

### FIELD OF THE INVENTION

The invention relates generally to semiconductor fabrication technology and, more particularly, to chemical vapor deposition (CVD) processing and associated apparatus for correcting temperature non-uniformities on semiconductor wafer surfaces.

### BACKGROUND OF THE INVENTION

In the fabrication of light-emitting diodes (LEDs) and other high-performance devices such as laser diodes, optical detectors, and field effect transistors, a chemical vapor deposition (CVD) process is typically used to grow a thin film stack structure using materials such as gallium nitride over a sapphire or silicon substrate. A CVD tool includes a process chamber, which is a sealed environment that allows infused gases to be deposited upon the substrate (typically in the form of wafers) to grow the thin film layers. A number of process parameters are controlled, such as temperature, pressure and gas flow rate, to achieve a desired crystal growth. Different layers are grown using varying materials and process parameters.

For example, devices formed from compound semiconductors such as III-V semiconductors typically are formed by growing successive layers of the compound semiconductor using metal organic chemical vapor deposition (MOCVD). In this process, the wafers are exposed to a combination of gases, typically including a metal organic compound as a source of a group III metal, and also including a source of a group V element which flow over the surface of the wafer while the wafer is maintained at an elevated temperature. Typically, the metal organic compound and group V source are combined with a carrier gas which does not participate appreciably in the reaction as, for example, nitrogen. One example of a III-V semiconductor is gallium nitride, which can be formed by reaction of an organo-gallium compound and ammonia on a substrate having a suitable crystal lattice spacing, as for example, a sapphire wafer. Typically, the wafer is maintained at a temperature on the order of 1000-1100° C. during deposition of gallium nitride and related compounds.

In a MOCVD process, where the growth of crystals occurs by chemical reaction on the surface of the substrate, the process parameters must be controlled with particular care to ensure that the chemical reaction proceeds under the required conditions. Even small variations in process conditions can adversely affect device quality and production yield. For instance, if a gallium and indium nitride layer is deposited, variations in wafer surface temperature will cause variations in the composition and bandgap of the deposited layer. Because indium has a relatively high vapor pressure, the deposited layer will have a lower proportion of indium and a greater bandgap in those regions of the wafer where the surface temperature is higher. If the deposited layer is an active, light-emitting layer of an LED structure, the emission wavelength of the LEDs formed from the wafer will also vary to an unacceptable degree.

In a MOCVD process chamber, semiconductor wafers on which layers of thin film are to be grown are placed on rapidly-rotating carousels, referred to as wafer carriers, to provide a uniform exposure of their surfaces to the atmosphere within the reactor chamber for the deposition of the semiconductor materials. Rotation speed is on the order of 1,000 RPM. The wafer carriers are typically machined out of a highly thermally conductive material such as graphite, and are often coated with a protective layer of a material such as silicon carbide. Each wafer carrier has a set of circular indentations, or pockets, in its top surface in which individual wafers are placed.

The wafer carrier is supported on a spindle within the reaction chamber so that the top surface of the wafer carrier having the exposed surfaces of the wafers faces upwardly toward a gas distribution device. While the spindle is rotated, the gas is directed downwardly onto the top surface of the wafer carrier and flows across the top surface toward the periphery of the wafer carrier. The used gas is evacuated from the reaction chamber through ports disposed below the wafer carrier. The wafer carrier is maintained at the desired elevated temperature by heating elements, typically electrical resistive heating elements disposed below the bottom surface of the wafer carrier. These heating elements are maintained at a temperature above the desired temperature of the wafer surfaces, whereas the gas distribution device typically is maintained at a temperature well below the desired reaction temperature so as to prevent premature reaction of the gases. Therefore, heat is transferred from the heating elements to the bottom surface of the wafer carrier and flows upwardly through the wafer carrier to the individual wafers.

The wafer carrier has different thermal properties from the wafers that it holds, including thermal conductivity, specific heat capacity, and thermal diffusivity. Depending on where each wafer is positioned in the wafer carrier, the heat transfer to that wafer from the heating elements and from the bulk material of the wafer carrier itself can vary. Additionally, the gas flow over the wafers varies depending on the radial position of each wafer, with outermost-positioned wafers being subjected to higher flow rates due to their faster velocity during rotation. Even on each individual wafer there can be temperature non-uniformities, i.e., cold spots and hot spots.

A great deal of effort has been devoted to system design features to minimize temperature variations during processing; however, the problem continues to present many challenges. For instance, thermal properties are themselves temperature-dependent; thus, the thermal profile, i.e., temperature distribution, of the wafers during CVD processing at a first temperature will be different from those at a different temperature. Since process recipes require different temperatures to facilitate formation of different lattice structures or different chemical reactions, the thermal non-uniformity problem is a dynamic one. Although a wafer carrier and heating elements can be designed to provide uniform heating for a particular process step—with a certain predefined gas temperature and wafer carrier temperature, and for certain material thicknesses—this optimization will be specific to those particular conditions. A more effective solution is needed to provide improved heating uniformity for the varying conditions in the processing steps of a multilayer CVD process.

### SUMMARY OF THE INVENTION

Aspects of the invention are directed to a chemical vapor deposition (CVD) system in which thermal non-uniformities are dynamically corrected. In one embodiment, a CVD apparatus has a reaction chamber which is adapted to have rotatably mounted therein a wafer carrier, the wafer carrier having at least one retention site for one or more wafers. The general heat source is preferably constructed and arranged to evenly heat the surface of the wafers. However, the general heat source applies heat to relatively large areas.

To correct for thermal non-uniformities in smaller localized areas, a localized temperature monitoring system is configured to provide localized temperature information representing surface temperatures of portions of the one or more wafers while the wafer carrier is rotating and a CVD process is carried out. A temperature profiling system is operatively coupled to the localized temperature monitoring system and configured to generate a temperature profile that is indicative of localized cold spots on a surface of the one or more wafers, the temperature profile being based on the localized temperature information.

A targeted heating system is operatively coupled to the temperature profiling system and configured to selectively apply localized heat to the localized cold spots dynamically, based on the temperature profile, such that a thermal distribution of the surface of the one or more wafers is made more uniform while a CVD process is carried out. The CVD process in which the localized temperature monitoring system measures temperature can be the same CVD process as the one in which the targeted heating system selectively applies localized heat to correct for cold spots. Alternatively, the CVD process in which the localized temperature monitoring is performed can be a separately-run process that precedes a subsequent process in which the corrections are made with the selectively-applied localized heat. In one type of embodiment, the targeted heating system utilizes an ultraviolet pulsed laser having a wavelength that is selected to have good absorption in the substrate material.

Another aspect of the invention is directed to a targeted temperature compensation subsystem for use with a CVD apparatus. The subsystem comprises a localized temperature monitoring system configured to provide localized temperature information based representing surface temperatures of portions of the one or more wafers while the wafer carrier is rotating and a first CVD process is carried out on the CVD apparatus; a temperature profiling system operatively coupled to the localized temperature monitoring system and configured to generate a temperature profile that is indicative of localized cold spots on a surface of the one or more wafers, the temperature profile being based on the localized temperature information; and a targeted heating system operatively coupled to the temperature profiling system and configured to selectively apply localized heat to the localized cold spots dynamically based on the temperature profile such that a thermal distribution of the surface of the one or more wafers is made more uniform while a second CVD process is carried out on the CVD apparatus. The first CVD process can be the same CVD process as the second one.

Another aspect of the invention is directed to a method for in-situ targeted temperature compensation for use with a chemical vapor deposition (CVD) apparatus that includes a reaction chamber adapted to have rotatably mounted therein a wafer carrier that retains one or more wafers. The method provides localized temperature information representing surface temperatures of portions of the one or more wafers while the wafer carrier is rotating and a CVD process is carried out on the CVD apparatus. A temperature profile is generated that is indicative of localized cold spots on a surface of the one or more wafers, the temperature profile being based on the localized temperature information. Localized heat is selectively applied to the localized cold spots dynamically based on the temperature profile. In a further aspect of the invention, an apparatus is provided for in-situ targeted temperature compensation for use with a chemical vapor deposition (CVD) apparatus that includes a reaction chamber adapted to have rotatably mounted therein a wafer carrier that retains one or more wafers. The apparatus includes means for providing localized temperature information representing surface temperatures of portions of the one or more wafers while the wafer carrier is rotating and a first CVD process is carried out on the CVD apparatus. Additionally, the apparatus includes means for generating a temperature profile that is indicative of localized cold spots on a surface of the one or more wafers, the temperature profile being based on the localized temperature information. Further, the apparatus comprises means for selectively applying localized heat to the localized cold spots dynamically based on the temperature profile such that a thermal distribution of the surface of the one or more wafers is made more uniform while a second CVD process is carried out on the CVD apparatus.

### BRIEF DESCRIPTION OF THE DRAWINGS

The invention may be more completely understood in consideration of the following detailed description of various embodiments of the invention in connection with the accompanying drawings, in which:

FIG. 1 illustrates a chemical vapor deposition apparatus in accordance with one embodiment of the invention.

FIG. 2 is a top view diagram illustrating a wafer carrier used with the apparatus of FIG. 1 according to one embodiment of the invention.

FIG. 3 is a cross-sectional view diagram taken along line 3-3 detailing a wafer retention site, also referred to herein as a wafer pocket, of the wafer carrier depicted in FIGS. 1 and 2.

FIG. 4 is a diagram illustrating a targeted temperature compensation system in greater detail according to one example embodiment.

FIG. 5 is an operational flow diagram illustrating a basic operation of a temperature profiling system according to one embodiment of the invention.

FIG. 6 is a functional block diagram illustrating the logical operation of a controller that is a part of a targeted heating system according to one embodiment.

FIG. 7 is a simplified diagram illustrating an exemplary mechanical arrangement of a laser source and targeting optics of a targeted heating system, in which the laser source is located outside of a CVD reaction chamber according to one embodiment.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

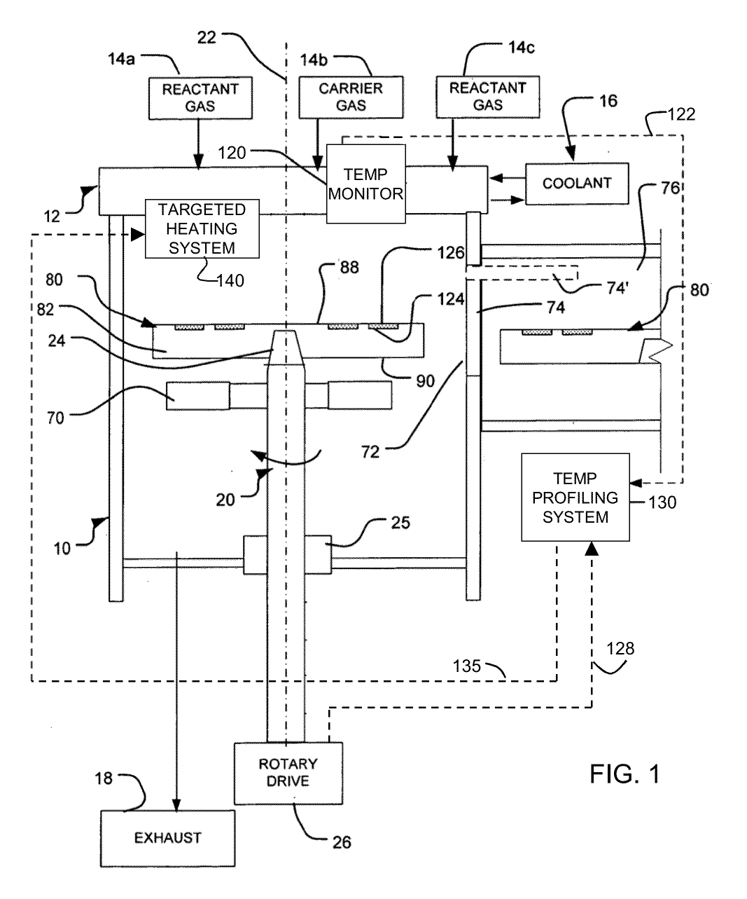

FIG. 1 illustrates a chemical vapor deposition apparatus in accordance with one embodiment of the invention. A reaction chamber 10 defines a process environment space. A gas distribution device 12 is arranged at one end of the chamber. The end having the gas distribution device 12 is referred to herein as the “top” end of the chamber 10. This end of the chamber typically, but not necessarily, is disposed at the top of the chamber in the normal gravitational frame of reference. Thus, the downward direction as used herein refers to the direction away from the gas distribution device 12; whereas the upward direction refers to the direction within the chamber, toward the gas distribution device 12, regardless of whether these directions are aligned with the gravitational upward and downward directions. Similarly, the “top” and “bottom” surfaces of elements are described herein with reference to the frame of reference of chamber 10 and gas distribution device 12.

Gas distribution device 12 is connected to sources 14a, 14b, 14c for supplying process gases to be used in the wafer treatment process, such as a carrier gas and reactant gases such as a metalorganic compound and a source of a group V metal. The gas distribution device 12 is arranged to receive the various gases and direct a flow of process gases generally in the downward direction. The gas distribution device 12 desirably is also connected to a coolant system 16 arranged to circulate a liquid through the gas distribution device so as to maintain the temperature of the gas distribution device at a desired temperature during operation. A similar coolant arrangement (not shown) can be provided for cooling the walls of chamber 10. Chamber 10 is also equipped with an exhaust system 18 arranged to remove spent gases from the interior of the chamber through ports (not shown) at or near the bottom of the chamber so as to permit continuous flow of gas in the downward direction from the gas distribution device.

A spindle 20 is arranged within the chamber so that the central axis 22 of the spindle extends in the upward and downward directions. The spindle is mounted to the chamber by a conventional rotary pass-through device 25 incorporating bearings and seals (not shown) so that the spindle can rotate about axis 22, while maintaining a seal between the spindle and the wall of chamber 10. The spindle has a fitting 24 at its top end, i.e., at the end of the spindle closest to the gas distribution device 12. As further discussed below, fitting 24 is an example of a wafer carrier retention mechanism adapted to releasably engage a wafer carrier. In the particular embodiment depicted, the fitting 24 is a generally frustoconical element tapering toward the top end of the spindle and terminating at a flat top surface. A frustoconical element is an element having the shape of a frustum of a cone. Spindle 20 is connected to a rotary drive mechanism 26 such as an electric motor drive, which is arranged to rotate the spindle about axis 22.

A heating element 70 is mounted within the chamber and surrounds spindle 20 below fitting 24. The chamber is also provided with an entry opening 72 leading to an antechamber 76, and a door 74 for closing and opening the entry opening. Door 74 is depicted only schematically in FIG. 1. and is shown as movable between the closed position shown in solid lines, in which the door isolates the interior of chamber 10 from antechamber 76, and an open position shown in broken lines at 74′. The door 74 is equipped with an appropriate control and actuation mechanism for moving it between the open position and closed positions. In practice, the door may include a shutter movable in the upward and downward directions as disclosed, for example, in U.S. Pat. No. 7,276,124, the disclosure of which is hereby incorporated by reference herein. The apparatus according to one embodiment further includes a loading mechanism (not shown) capable of moving a wafer carrier from the antechamber 76 into the chamber and engaging the wafer carrier with the spindle in the operative condition, and also capable of moving a wafer carrier off of the spindle and into the antechamber.

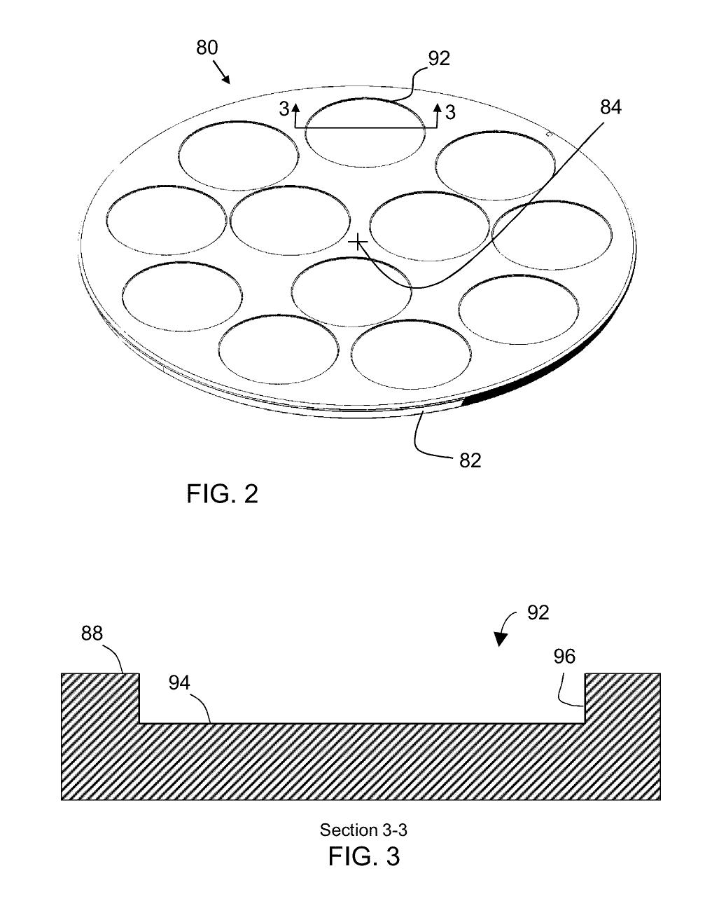

The apparatus works with a plurality of wafer carriers 80. In the operating condition shown in FIG. 1, a first wafer carrier 80 is disposed inside chamber 10 in an operative position, whereas a second wafer carrier 80 is disposed within antechamber 76. Each wafer carrier 80 includes a body 82 which is substantially in the form of a circular disc having a central axis 84 (FIG. 2). In the operative position the central axis 84 of the wafer carrier body is coincident with the axis 22 of the spindle. The body 82 may be formed as a single piece or as a composite of plural pieces. For example, as disclosed in U.S. Patent Application Pub. No. 20090155028, the disclosure of which is hereby incorporated by reference herein, the wafer carrier body may include a hub defining a small region of the body surrounding the central axis 84 and a larger portion defining the remainder of the disc-like body. The body desirably is formed from materials which do not contaminate the process and which can withstand the temperatures encountered in the process. For example, the larger portion of the disc may be formed largely or entirely from materials such as graphite, silicon carbide, or other refractory materials. The body has a generally planar top surface 88 and a bottom surface 90 extending generally parallel to one another and generally perpendicular to the central axis 84 of the disc. The body also has a plurality of wafer-holding features adapted to hold a plurality of wafers.

As illustrated in FIGS. 2 and 3, each wafer-holding feature includes a wafer retention site in the form of a generally circular pocket 92 extending downwardly into the body from the top surface 88. The generally circular shape is made to correspond to the shape of the wafers. Each pocket 92 has a floor surface 94 disposed below the surrounding portions of the top surface 88. Each pocket also has a peripheral wall surface 96 surrounding the floor surface and defining the periphery of the pocket. The peripheral wall surface 96 extends downwardly from the top surface 88 of the body to the floor surface. In various embodiments, the peripheral wall surface may slope outwardly, away from the center of the pocket, over at least a portion of the periphery. In particular, those portions of the peripheral wall surface furthest from the central axis 84 of the wafer carrier desirably slope outwardly, away from the central axis 84 of the wafer carrier in the direction down toward the floor surface 94. In addition, the floor surface 94 in some embodiment may include standoff features that raise the wafer off lower portions of floor surface 94, thereby permitting some flow of gas around the edges and below the bottom surface of the wafers.

In operation, a wafer 124, such as a disc-like wafer formed from sapphire, silicon carbide, or other crystalline substrate, is disposed within each pocket 90 of each wafer carrier 80. Typically, the wafer 124 has a thickness which is small in comparison to the dimensions of its major surfaces. For example, a circular wafer of about 2 inches (50 mm) in diameter may be about 430 μm thick or less. As best seen in FIG. 2, the wafer is disposed with a top surface 126 facing upwardly, so that the top surface is exposed at the top of the wafer carrier. It should be noted that in various embodiments, wafer carrier 80 carries different quantities of wafers. For instance, in one example embodiment, wafer carrier 80 is adapted to hold one single wafer.

In a typical MOCVD process, a wafer carrier 80 with wafers loaded thereon is loaded from antechamber 76 into chamber 10 and placed in the operative position shown in FIG. 1. In this condition, the top surfaces of the wafers face upwardly, towards the gas inlet structure 12. Heater 70 is actuated, and the rotary drive mechanism 26 operates to turn spindle 20 and hence wafer carrier 80 around axis 22. Typically, the spindle is rotated at a rotational speed from about 50-1500 revolutions per minute. Process gas supply units 14a, 14b, and 14c are actuated to supply gases through the gas distribution device 12. The gases pass downwardly toward the wafer carrier 80, over the top surface 88 of the wafer carrier and the top surfaces 126 of the wafers, and downwardly around the periphery of the wafer carrier to the outlet and to exhaust system 18. Thus, the top surface of the wafer carrier and the top surfaces of the wafer are exposed to a process gas including a mixture of the various gases supplied by the various process gas supply units. Most typically, the process gas at the top surface is predominantly composed of the carrier gas supplied by carrier gas supply unit 14b. In a typical chemical vapor deposition process, the carrier gas may be nitrogen, and hence the process gas at the top surface of the wafer carrier is predominantly composed of nitrogen with some amount of the reactive gas components.

Heaters 70 transfer heat to the bottom surface 90 of the wafer carrier, principally by radiant heat transfer. The heat applied to the bottom surface of the wafer carrier flows upwardly through the body 82 of the wafer carrier to the top surface 88 of the wafer carrier. Heat passing upwardly through the body also passes upwardly through gaps to the bottom surface of each wafer, and upwardly through the wafer to the top surface 126 of the wafer. Heat is radiated from the top surface 88 of the wafer carrier and from the top surfaces 126 of the wafer to the colder elements of the process chamber as, for example, to the walls of the process chamber and to the gas distribution device 12. Heat is also transferred from the top surface 88 of the wafer carrier and the top surfaces 126 of the wafers to the process gas passing over these surfaces.

The system includes a number of features designed to provide uniform heating of the surfaces 126 of each wafer 124. However, a variety of causes still create thermal non-uniformities on the surfaces of the wafers. These include dynamic variations in the flow of gas over and around each wafer as a result of the growth of crystalline structure on the surface 126 of the wafers, warping of the wafer, and the like. The changing structures also affect conductivity of heat through the materials of the surface of the wafers. For example, where the process involves chemical vapor deposition and epitaxial growth on the top surface of the substrate, the deposited material may have a normal, unconstrained lattice spacing, different from that of the wafer material. This tends to induce compressive or tensile deformation of the top surface, leading to warpage of the wafers. The emissivity of the wafer top surfaces also may change during the process. As discussed above, various processing steps at different temperatures will experience different heat transfer dynamics due to temperature dependencies of the heat transfer properties of materials. A number of other causes can contribute to temperature non-uniformities. Moreover, the pattern of non-uniformity tends to change during processing.

One aspect of the invention is directed to in-situ correction of temperature non-uniformities. In the example embodiment depicted in FIG. 1 a targeted temperature compensation subsystem includes a temperature monitor 120, a temperature profiling system 130, and a targeted heating system 140. These systems are operatively coupled with one another and with other parts of the CVD apparatus such as rotary drive mechanism 26.

In operation, the targeted temperature compensation subsystem monitors local temperature on surface 126 of each wafer. Temperature monitor 120 is arranged to monitor the surface temperatures of wafers being treated during the process and to provide temperature information 122 representing the surface temperature of a measured localized area on the surface 156 of wafers 124 during the process. Temperature information 122 can include temperature monitor positional information that represents a coordinate of the localized area (e.g., radius from central axis 22). Temperature monitor 120 can be mounted on gas distribution device 12 as depicted in FIG. 1, or elsewhere in the reaction chamber 10. In various embodiments, portions of temperature monitor 120 are inside the reaction chamber 10 and portions of temperature monitor 120 are installed on the exterior of the reaction chamber 10. In another embodiment, temperature monitor 120 is installed entirely on the exterior of reaction chamber 10. In embodiments where portions, or all, of temperature monitor 120 is external to reaction chamber 10, temperature monitor 120 is operatively coupled to the process via a suitable optical port capable of transmitting the light wavelengths of interest.

In various embodiments, the temperature monitor 120 uses a variety of suitable measurement techniques. For instance, in one approach, temperature monitor 120 uses one or more pyrometers such as those sold under the trademark REALTEMP™ by the Veeco Instrument Corporation of Plainview, N.Y. These measurements can be performed throughout the processing in real-time. It should be noted that a measurement of absolute temperature is not required in some embodiments; rather, a relative temperature measurement is performed on various target areas, from which an average or nominal reference temperature can be ascertained along with hot spots and cold spots as deviations from the nominal.

In another embodiment, a results-based temperature uniformity measurement technique is employed that infers and localizes the presence and location of temperature non-uniformities once certain structures have been formed on the wafer. In one such approach, a photoluminescence (PL) system is utilized in which a laser excites a target area on the surface of a wafer and optical sensing instrumentation measures the resulting photoluminescence from the crystal lattice, such as multiple-quantum-well (MQW) LED heterostructures, on the surface of the wafer. This PL approach measures the temperature non-uniformities indirectly, based on the properties of the produced devices.

The localization of the temperature monitoring can vary from one embodiment to another. In general, however, the temperature monitoring is localized to a selected portion of a given wafer. In one particular embodiment, the temperature monitoring is localized to a resolution on the order of a centimeter. In another embodiment, the resolution is on the order of a millimeter.

Temperature profiling system 130 receives temperature information 122, which can include a temperature and temperature monitoring positional information from temperature monitor 120. In addition, temperature profiling system 130 receives wafer carrier positional information 128, which in one embodiment can come from rotary drive mechanism 26. Wafer carrier positional information 128, when time-synchronized with the temperature information 122, can represent another coordinate of the localized area being measured (e.g., rotational angle of the wafer carrier). With this information, temperature profiling system 130 constructs a temperature profile of the wafers 124 on wafer carrier 80. The temperature profile represents a thermal distribution on the surface 126 of each of the wafers 124.

In certain approaches, the temperature profile is a dynamic representation in that the profile changes over time. In various embodiments, the temperature profile represents a portion of the surface of each wafer. For instance, in one embodiment, a current temperature profile represents the temperature distribution along a particular radius (or range of radii) from central axis 22. In another embodiment, a temperature profile of an entire surface of one or more of the wafers is stored as a current temperature profile. In another embodiment, the temperature profile is constantly updated, portion-by-portion, as temperature and positional data is obtained. In this latter embodiment, the temperature profile is constantly varying.

Temperature profiling system 130 produces temperature profile information 135, which represents a heat map of at least a portion of the wafer surfaces. The temperature profile information includes temperature information and location information for each measured area on the surfaces of the wafers. In one embodiment, temperature profiling system 130 associates temperature measurement information of a localized area and localization positional information corresponding to the localized area provided by the localized temperature monitoring system with positional information of the wafer carrier representing a rotational position that the wafer carrier had for each data point of the temperature measurement information. These items of data can be represented using any suitable format such as, for instance, a table data structure. In other embodiments, the temperature profile information 135 takes a very different form such as, for instance, one or more analog signals.

Targeted heating system 140 uses the temperature profile information 135 to correct temperature non-uniformities on the surface of the wafers detected by temperature monitor 120 and mapped by temperature profiling system 130. In one type of embodiment, targeted heating system 140 selectively applies heat to areas determined to be cold spots. As a result, the temperature of the cold spots is raised to match (on average) the nominal temperature of the greater region on the wafer. Notably, this temperature correction process is carried out while the CVD process is taking place. Thus, the temperature correction is controlled process that is a part of the overall CVD processing.

In one type of embodiment, temperature correction is carried out close in time to when the thermal non-uniformities are measured and detected. Thus, in this embodiment, a closed-loop temperature control is achieved. Regardless of the cause of the thermal non-uniformities, and regardless any variation from process run to process run, the thermal non-uniformities are corrected based on their current condition.

In another type of embodiment, the temperature correction is carried out at a time which is significantly later than when the thermal non-uniformities are measured and detected. For example, the temperature correction according to this type of embodiment can be applied in a subsequent processing run based on temperature profile information collected during one or more previous processing runs of the same recipe. This is an open-loop system that relies on there being a high degree of repeatability in the temperature non-uniformities from run-to-run. Although the embodiments discussed in detail below focus more on the closed-loop system, it should be understood that the basic principles are applicable to an open loop system as well, with appropriate system and operational adjustments made to accommodate the differences between these two types of approaches. For example, instead of feeding temperature profile information 135 right away to the targeted heating system 140, the temperature profile information is stored, as a function of time, on a storage medium, which is then read in the subsequent process run in which the temperature corrections are applied.

In one embodiment, targeted heating system 140 includes a laser system having a laser source and a set of optics that collimate and focus the laser beam of a set size and shape onto the surface of the wafers. Targeted heating system 140 also includes a mechanism for targeting the beam onto a selectable location, and a mechanism for regulating the average power of the beam. The laser source, in one embodiment, is an ultraviolet (UV) pulse laser with a suitable UV wavelength for high absorption by the material of the wafer. Average power can be modulated using a variety of techniques such as, for instance, a radio frequency (RF) controlled Q-switching arrangement. In another embodiment, an acoustic optical modulator is used to vary the average power output of the laser. A variety of techniques can be employed in aiming the laser. One such technique uses scanning optics. Another approach uses a linear positioning mechanism for either the laser source, or for targeting optics that direct the laser beam to the desired target area.

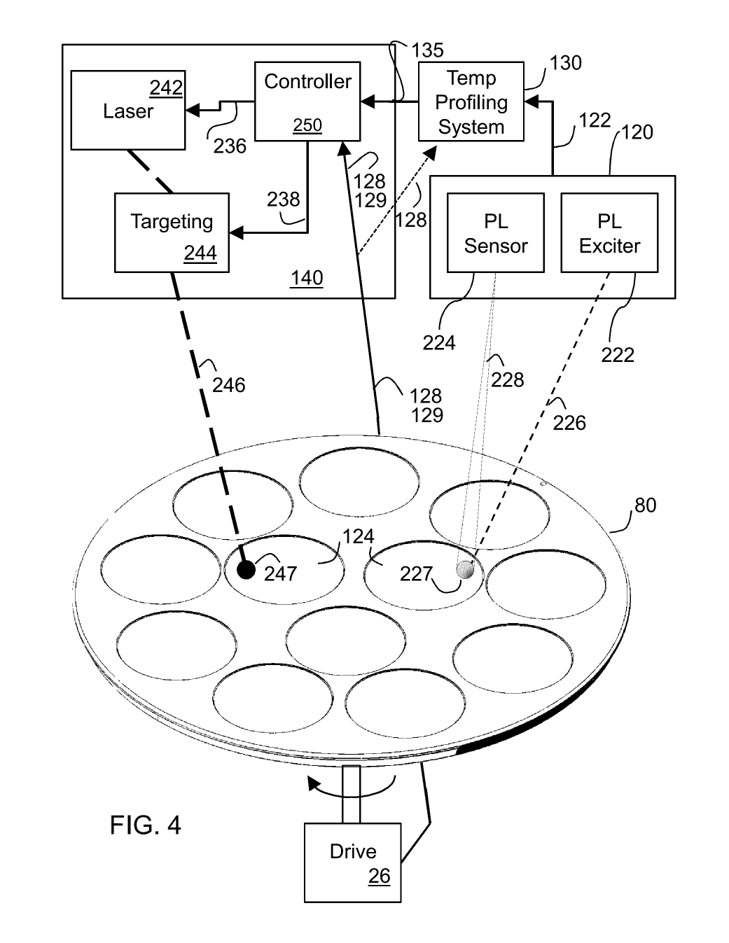

FIG. 4 is a diagram illustrating the targeted temperature compensation system according to one example embodiment in greater detail. In this embodiment, temperature monitor 120 includes a photoluminescence (PL) exciter 222 and a PL sensor 224. PL exciter emits a relatively low-power laser beam 226 onto a measurement target area 227. PL sensor 224 has optics that establish a focus 228 on measurement target area 227. PL sensor 224 measures the wavelength, intensity, or both, of measurement target area 227. The measured parameters are represent a localized temperature of the measurement target area 227 during processing, relative to other measured target areas. Temperature monitor 120 also includes a positioning mechanism (not shown) that repositions target area 227. Any suitable positioning technique can be utilized according to embodiments of the invention. Examples include optical scanners (e.g., using adjustable mirrors), or linear positioning systems that can move PL exciter 222 and PL sensor 224 along a radial direction (relative to wafer carrier 80). Rotation of wafer carrier 80, along with time synchronization of the temperature information 122, allows any point along the surface of the wafers 124 to be measured.

Temperature profiling system 130 receives temperature information 122, along with positional information 128. In the embodiments depicted in the drawings, the positional information 128 is provided by rotary drive mechanism 26, wherein the positional information can be produced by an encoder device that measures an angular position of the drive mechanism, by an output from a motor drive circuit (e.g., in cases where the rotary drive mechanism 26 is a stepper motor rather than a servo motor with a feedback system), for example. In other embodiments, however, any other suitable source for positional information may be utilized, such as an optical positional detection system that is entirely separate from rotary drive mechanism 26. One such system may use fiducial marks on the wafer carrier 80 or on the wafers themselves to determine the rotational position of the wafer carrier. With the temperature and positional information, temperature profiling system 130 creates temperature profile information 135.

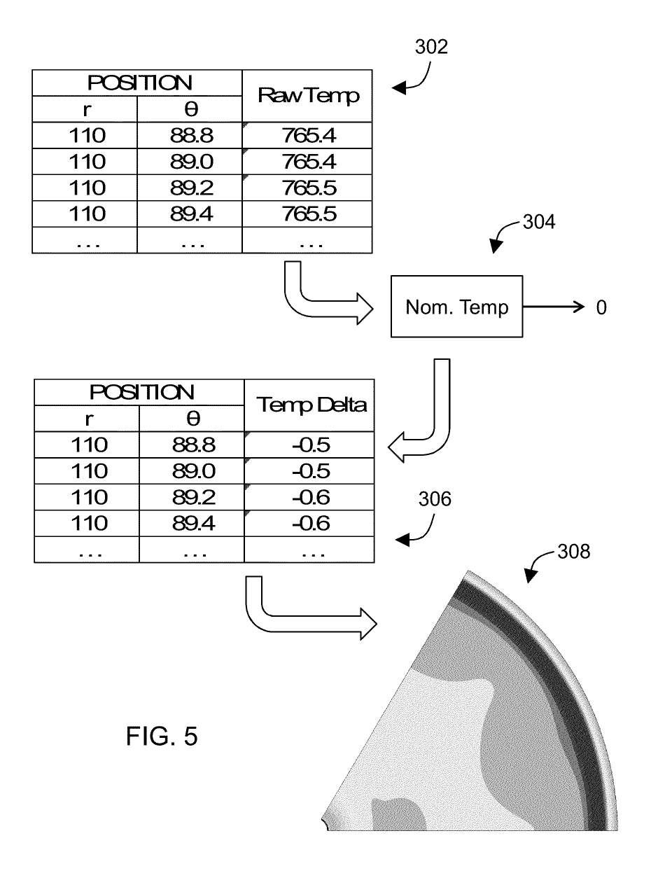

FIG. 5 is an operational flow diagram illustrating a basic operation of temperature profiling system 130 according to one embodiment of the invention. At 302, a raw set of data is collected from temperature information 122 and wafer carrier positional information 128. In the example depicted, the raw temperature data in the right-most column of the table at 302 is provided by temperature monitor 120. This data may or may not be accurate; however, the data is preferably repeatable (i.e., precise). The radial positional information r in the left-most column of the table at 302 is provided by the measurement target area positioning system. Both of these items of information are included as part of temperature information 122 according to this example embodiment. The angular position 0 in the middle column of the table at 302 is provided by the carrier positional information 128.

At 304, temperature profiling system 130 normalizes the temperature data. In this operation, an large set of measured temperatures is mathematically combined (e.g., averaged) using a statistical summary function to determine a nominal temperature value. At 306, the measured individual values are compared against the nominal value to determine if they represent hot spots, cold spots, or correct temperature spots. The temp delta column in the table at 306 indicates examples of cold spots that are about ½ a degree below nominal. Taken as a whole, the temperature data represents a heat map such as the one depicted at 308. The data may be further tagged (e.g., with time values) or with additional information and may be re-formatted at this stage. For instance, cold spots that are candidates for temperature correction can be represented in a more efficient manner in terms of their boundaries and deviation from the nominal temperature. This particularized temperature profile information is then passed to targeted heating system 140.

Referring again to FIG. 4, targeted heating system 140 includes laser 242, targeting optics 244, and controller 250. Laser 242 generates the beam at a particular energy level, which may be controlled by Q-switching to adjust a duty cycle of the laser pulses. The beam is directed by targeting optics 244 onto a heating target area 247 on wafer 124 as shown. Controller 250 provides power modulation control signal 236 to laser 242 and targeting control signal 238 to targeting optics 244.

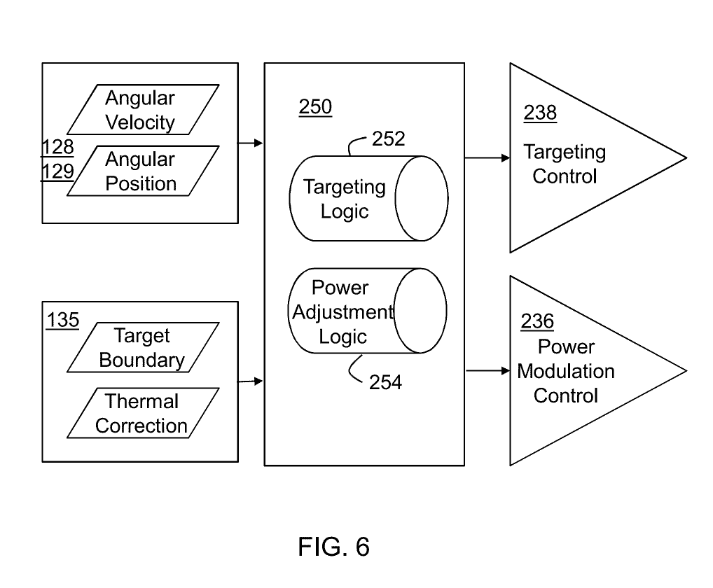

FIG. 6 is a functional block diagram illustrating the logical operation of controller 250. Wafer carrier positional information 128 and angular velocity information 129 are provided as an input to controller 250. The temperature profile information 135, which in this example includes an identification of the target boundary and thermal correction of a cold spot to be corrected, is another input to controller 250. Controller 250 is programmed with targeting logic 252 and power adjustment logic 254. Targeting logic 252 associates the angular position and angular velocity of the spinning wafer carrier, as well as the location of the target cold spot, with positioning and timing information for aiming the laser beam 246. For example, targeting logic includes logic for determining when to start application of laser beam 246 relative to the spinning wafer carrier. Also, targeting logic determines the duration of the application of the laser beam 246. This latter determination takes into account factors such as the angular velocity of the wafer carrier and radial distance of the cold spot to be heated, which together define a linear velocity of the cold spot. For a scanning laser embodiment, this information defines the scanning path to take to track the cold spot. In a non-scanning embodiment, this information is needed to define where along the radius of wafer carrier 80 to position the laser beam 246, how long to apply the beam to cover the cold spot as it appears in the heating target area 247. The input parameters are processed according to the targeting logic to produce targeting control signal 238.

Notably, the measured cold spot can be measured while the rotating wafer carrier is in a different position than when the laser 246 is applied to heat the cold spot. This arrangement is illustrated in FIG. 4, where the localized temperature sensing is taking place on one wafer, whereas the targeted heating is applied to another wafer. For heating the cold spot measured under area 227 from a different location than measured area 227, a positional correction is computed by targeting logic 252.

Power adjustment logic 254 takes into account the thermal correction needed to maintain the cold spot at the nominal temperature, along with the motional parameters of the positional information 128 and angular velocity information 129 (which define how long the cold spot will be in position below the target heating area 247 in the non-scanning embodiment). These input parameters are used to set the laser power for the power modulation control output 236. In a related embodiment, power adjustment logic 254 additionally takes into account the number of cold spots to correct and thus the time interval between opportunities to re-apply the laser beam 246 to a particular cold spot. This information, together with the motional parameters and the positioning system response time, can be used to determine an amount of hysteresis, or over-correction to be applied to a given cold spot in order to maintain that spot at an average temperature that is approximately equal to the nominal temperature.

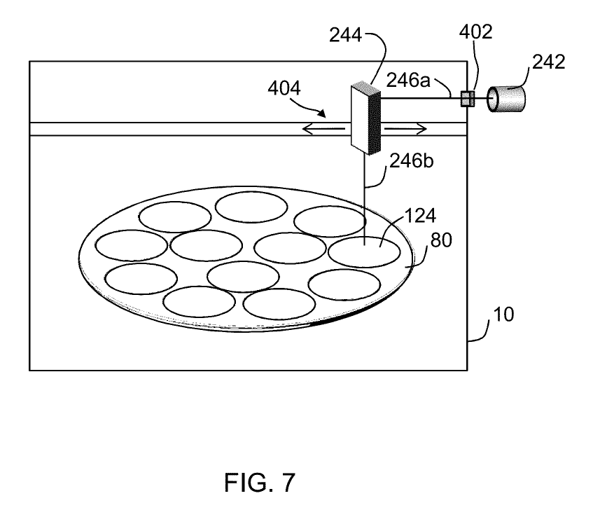

FIG. 7 is a simplified diagram illustrating an exemplary arrangement for a laser 242 and targeting optics 244, wherein the laser source 242 is located outside of reaction chamber 10. In this embodiment, laser 242 directs beam 246a through a transparent port 402 into targeting optics 244, which in turn re-direct the beam 246b onto wafer 124. In one embodiment, targeting optics 244 include a scanning arrangement that can point the beam 246b along various angles. In another embodiment, as illustrated in FIG. 7, targeting optics 244 are movable along a linear axis 404 which is parallel to beam 246a and is aligned generally radially over wafer carrier 80 so that beam 246b can be positioned over all portions of interest of wafers 124. Mechanically, in one embodiment, the linear motion can be accomplished by means of a motorized linear slide.

The embodiments of the present invention provide improved temperature uniformity in CVD processes. In one type of embodiment, targeted temperature corrections are accomplished in real-time, and are themselves dynamic to account for changing temperatures and structures during the processing. In another type of embodiment, the targeted temperature corrections are accomplished in a subsequent process run based on data collected during or after a previous run.

The embodiments above are intended to be illustrative and not limiting. Additional embodiments are within the claims. In addition, although aspects of the present invention have been described with reference to particular embodiments, those skilled in the art will recognize that changes can be made in form and detail without departing from the scope of the invention, as defined by the claims.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention may comprise a combination of different individual features selected from different individual embodiments, as will be understood by persons of ordinary skill in the art.

Any incorporation by reference of documents above is limited such that no subject matter is incorporated that is contrary to the explicit disclosure herein. Any incorporation by reference of documents above is further limited such that no claims that are included in the documents are incorporated by reference into the claims of the present Application. The claims of any of the documents are, however, incorporated as part of the disclosure herein, unless specifically excluded. Any incorporation by reference of documents above is yet further limited such that any definitions provided in the documents are not incorporated by reference herein unless expressly included herein.

For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A system for growing epitaxial layers on one or more wafers by chemical vapor deposition (CVD), said system comprising:
a reaction chamber adapted to have rotatably mounted therein a wafer carrier, the wafer carrier having at least one retention site for the one or more wafers;
a localized temperature monitoring system configured to provide localized temperature information representing surface temperatures of portions of the one or more wafers while the wafer carrier is rotating and a first CVD process is carried out;
a temperature profiling system operatively coupled to the localized temperature monitoring system and configured to generate a temperature profile that is indicative of localized cold spots on a surface of the one or more wafers, the temperature profile being based on the localized temperature information; and
a targeted heating system operatively coupled to the temperature profiling system and configured to selectively apply localized heat to the localized cold spots dynamically based on the temperature profile such that a thermal distribution of the surface of the one or more wafers is made more uniform while a second CVD process is carried out.

2. The system of claim 1, further comprising:
a rotary drive mechanism adapted to be operatively coupled to the wafer carrier and configured to impart rotational motion to the wafer carrier about a central axis that is perpendicular to a major surface of the wafer carrier.

3. The system of claim 1, wherein the first CVD process is the same CVD process as the second CVD process.

4. The system of claim 1, wherein the first CVD process is a different CVD process from the second CVD process and is carried out at a different time, wherein the first CVD process and the second CVD process have a common recipe.

5. The system of claim 1, wherein the localized temperature monitoring system includes a first portion that is situated in the reaction chamber and a second portion that is outside of the reaction chamber.

6. The system of claim 1, wherein the temperature profile represents temperature distribution of at least a portion of the surfaces of the one or more wafers as a function of time.

7. The system of claim 1, wherein the temperature profiling system is adapted to continuously update the temperature profile during operation of a CVD process.

8. The system of claim 1, wherein the temperature profiling system is adapted to associate temperature measurement information of a localized area and localization positional information corresponding to the localized area provided by the localized temperature monitoring system with positional information of the wafer carrier representing a rotational position that the wafer carrier had for each data point of the temperature measurement information.

9. The system of claim 1, wherein the temperature profiling system is adapted to normalize raw temperature information based on a statistical summary function to determine a deviation from a nominal temperature value at each of a plurality of localized measurement areas.

10. The system of claim 1, wherein the targeted heating system comprises a first portion situated in the reaction chamber and a second portion situated outside of the reaction chamber.

11. The system of claim 1, wherein the targeted heating system comprises a laser source and targeting optics adapted to direct a laser beam from the laser source to a heating target area on a surface of the one or more wafers while the wafer carrier is rotating during the second CVD process.

12. The system of claim 1, wherein the targeted heating system comprises a localized heat source and a controller adapted to dynamically control repositioning of the application of heat from the localized heat source to a heating target area on a surface of the one or more wafers while the wafer carrier is rotating during the second CVD process.

13. The system of claim 12, wherein the controller includes targeting logic adapted to process position and motion information relating to the wafer carrier and the temperature profile information to produce a targeting control signal for the localized heat source to dynamically control the repositioning of the application of heat.

14. The system of claim 12, wherein the controller includes power adjustment logic adapted to process position and motion information relating to the wafer carrier and the temperature profile information to produce a power modulation control signal for the localized heat source to dynamically control a power a heating power output.

15. A targeted temperature compensation subsystem for use with a chemical vapor deposition (CVD) apparatus that includes a reaction chamber adapted to have rotatably mounted therein a wafer carrier that retains one or more wafers, the subsystem comprising:
a localized temperature monitoring system configured to provide localized temperature information representing surface temperatures of portions of the one or more wafers while the wafer carrier is rotating and a first CVD process is carried out on the CVD apparatus;
a temperature profiling system operatively coupled to the localized temperature monitoring system and configured to generate a temperature profile that is indicative of localized cold spots on a surface of the one or more wafers, the temperature profile being based on the localized temperature information; and
a targeted heating system operatively coupled to the temperature profiling system and configured to selectively apply localized heat to the localized cold spots dynamically based on the temperature profile such that a thermal distribution of the surface of the one or more wafers is made more uniform while a second CVD process is carried out on the CVD apparatus.

16. The subsystem of claim 15, wherein the first CVD process is the same CVD process as the second CVD process.

17. The subsystem of claim 15, wherein the first CVD process is a different CVD process from the second CVD process and is carried out at a different time, wherein the first CVD process and the second CVD process have a common recipe.

18. The subsystem of claim 15, wherein the localized temperature monitoring system includes a noncontact temperature probe selected from the group consisting of: a pyrometer, a photoluminescence sensing system, or any combination thereof.

19. The subsystem of claim 15, wherein the localized temperature monitoring system is configured to supply temperature measurement information of a localized area and localization positional information corresponding to the localized area.

20. The subsystem of claim 15, wherein the temperature profile represents temperature distribution of at least a portion of the surfaces of the one or more wafers as a function of time.

21. The subsystem of claim 15, wherein the temperature profiling system is adapted to associate temperature measurement information of a localized area and localization positional information corresponding to the localized area provided by the localized temperature monitoring system with positional information of the wafer carrier representing a rotational position that the wafer carrier had for each data point of the temperature measurement information.

22. The subsystem of claim 15, wherein the temperature profiling system is adapted to identify location and degree of temperature non-uniformity of the cold spots.

23. The subsystem of claim 15, wherein the targeted heating system comprises a laser source and targeting optics adapted to direct a laser beam from the laser source to a heating target area on a surface of the one or more wafers while the wafer carrier is rotating during the second CVD process.

24. The subsystem of claim 15, wherein the targeted heating system comprises a localized heat source and a controller adapted to dynamically control repositioning of the application of heat from the localized heat source to a heating target area on a surface of the one or more wafers while the wafer carrier is rotating during the second CVD process.

25. The subsystem of claim 24, wherein the controller includes targeting logic adapted to process position and motion information relating to the wafer carrier and the temperature profile information to produce a targeting control signal for the localized heat source to dynamically control the repositioning of the application of heat.

26. The subsystem of claim 24, wherein the controller includes power adjustment logic adapted to process position and motion information relating to the wafer carrier and the temperature profile information to produce a power modulation control signal for the localized heat source to dynamically control a power a heating power output.

27. A method for in-situ targeted temperature compensation for use with a chemical vapor deposition (CVD) apparatus that includes a reaction chamber adapted to have rotatably mounted therein a wafer carrier that retains one or more wafers, the method comprising:
providing localized temperature information representing surface temperatures of portions of the one or more wafers while the wafer carrier is rotating and a first CVD process is carried out on the CVD apparatus;
generating a temperature profile that is indicative of localized cold spots on a surface of the one or more wafers, the temperature profile being based on the localized temperature information;
selectively applying localized heat to the localized cold spots dynamically based on the temperature profile such that a thermal distribution of the surface of the one or more wafers is made more uniform while a second CVD process is carried out on the CVD apparatus.

28. The method of claim 27, wherein the first CVD process is the same CVD process as the second CVD process.

29. The method of claim 27, wherein the first CVD process is a different CVD process from the second CVD process and is carried out at a different time, wherein the first CVD process and the second CVD process have a common recipe.

30. The method of claim 27, wherein providing the localized temperature monitoring system includes supplying temperature measurement information of a localized area and localization positional information corresponding to the localized area.

31. The method of claim 27, wherein generating the temperature profile includes representing a temperature distribution of at least a portion of the surfaces of the one or more wafers as a function of time.

32. The method of claim 27, wherein generating the temperature profile includes associating temperature measurement information of a localized area and localization positional information corresponding to the localized area with positional information of the wafer carrier representing a rotational position that the wafer carrier had for each data point of the temperature measurement information.

33. The method of claim 27, wherein selectively applying the heat includes operating a laser source and targeting optics adapted to direct a laser beam from the laser source to a heating target area on a surface of the one or more wafers while the wafer carrier is rotating during the second CVD process.

34. The method of claim 27, wherein selectively applying the heat includes dynamically controlling repositioning of the application of heat from a localized heat source to a heating target area on a surface of the one or more wafers while the wafer carrier is rotating during the second CVD process.

35. The method of claim 34, wherein selectively applying the heat includes processing position and motion information relating to the wafer carrier and the temperature profile information to produce a targeting control signal for the localized heat source to dynamically control the repositioning of the application of heat.

36. The method of claim 34, wherein selectively applying the heat includes processing position and motion information relating to the wafer carrier and the temperature profile information to produce a power modulation control signal for the localized heat source to dynamically control a power a heating power output.

37. An apparatus for in-situ targeted temperature compensation for use with a chemical vapor deposition (CVD) apparatus that includes a reaction chamber adapted to have rotatably mounted therein a wafer carrier that retains one or more wafers, the apparatus comprising:
means for providing localized temperature information representing surface temperatures of portions of the one or more wafers while the wafer carrier is rotating and a first CVD process is carried out on the CVD apparatus;
means for generating a temperature profile that is indicative of localized cold spots on a surface of the one or more wafers, the temperature profile being based on the localized temperature information;
means for selectively applying localized heat to the localized cold spots dynamically based on the temperature profile such that a thermal distribution of the surface of the one or more wafers is made more uniform while a second CVD process is carried out on the CVD apparatus.

38. The apparatus of claim 37, wherein the first CVD process is the same CVD process as the second CVD process.

39. The apparatus of claim 37, wherein the first CVD process is a different CVD process from the second CVD process and is carried out at a different time, wherein the first CVD process and the second CVD process have a common recipe.

40. The apparatus of claim 37, wherein the means for providing the localized temperature monitoring system include means for supplying temperature measurement information of a localized area and localization positional information corresponding to the localized area.

41. The apparatus of claim 37, wherein the means for generating the temperature profile include means for representing a temperature distribution of at least a portion of the surfaces of the one or more wafers as a function of time.

42. The apparatus of claim 37, wherein the means for generating the temperature profile include means for associating temperature measurement information of a localized area and localization positional information corresponding to the localized area with positional information of the wafer carrier representing a rotational position that the wafer carrier had for each data point of the temperature measurement information.

43. The apparatus of claim 37, wherein the means for selectively applying the localized heat include means for operating a laser source and targeting optics adapted to direct a laser beam from the laser source to a heating target area on a surface of the one or more wafers while the wafer carrier is rotating during the second CVD process.

44. The apparatus of claim 37, wherein the means for selectively applying the localized heat include means for dynamically controlling repositioning of the application of heat from a localized heat source to a heating target area on a surface of the one or more wafers while the wafer carrier is rotating during the second CVD process.

45. The apparatus of claim 44, wherein the means for selectively applying the localized heat include means for processing position and motion information relating to the wafer carrier and the temperature profile information to produce a targeting control signal for the localized heat source to dynamically control the repositioning of the application of heat.

46. The apparatus of claim 44, wherein the means for selectively applying the localized heat include means for processing position and motion information relating to the wafer carrier and the temperature profile information to produce a power modulation control signal for the localized heat source to dynamically control a power a heating power output.
